(19) United States
(12) Patent Application Publication
(10) Pub. No.: US 2024/0168095 A1
(43) Pub. Date: May 23, 2024

(54) Method and Apparatus for Predictive Diagnosis of a Device Battery of a Technical Device Using a Multivariate Transformer Model

(71) Applicant: Robert Bosch GmbH, Stuttgart (DE)

(72) Inventors: Christian Simonis, Leonberg (DE); Andras Gabor Kupcsik, Herrenberg (DE); Parameswaran Krishnan, Ayalur (IN)

(21) Appl. No.: 18/511,420

(22) Filed: Nov. 16, 2023

(30) Foreign Application Priority Data
Nov. 17, 2022 (DE) 10 2022 212 239.9

(51) Int. Cl. G01R 31/367; G01R 31/392

(52) U.S. Cl. CPC G01R 31/367; G01R 31/392

(57) ABSTRACT

A method of monitoring a device battery for predictively detecting a fault in the device battery in a technical device includes providing a historical temporal operating variable curve of several operating variables of a specific device battery, and providing a predicted temporal operating variable curve dependent on a usage pattern model, which is dependent on a usage behavior characterizing a type of use of the device battery. The method further includes determining a time series of input variable vectors each with elements which comprise one or more operating variables and/or one or more variables derived therefrom for a time step. A time series includes time steps from the historical and predicted operating variable curves. The method further includes evaluating a data-based anomaly prediction model comprising a data-based time series transformer model and a data-based prediction model.

This application claims priority under 35 U.S.C. § 119 to patent application no. DE 10 2022 212 239.9, filed on Nov. 17, 2022 in Germany, the disclosure of which is incorporated herein by reference in its entirety.

The disclosure relates to methods for diagnosing device batteries for technical devices, in particular methods for predictive diagnosis of device batteries by anomaly detection.

### BACKGROUND

The supply of energy to electrical devices and machines operated independent of a network, e.g., electrically powerable motor vehicles, is normally performed by means of device batteries or vehicle batteries. The latter supply electrical energy used to operate the devices.

Device batteries degrade over their service life and according to their load or usage. Referred to as aging, the result is a continuously decreasing maximum power or storage capacity. The aging state corresponds to a measure used to indicate the aging of energy storage means. Conventionally, a new device battery can have a 100% aging state (regarding its capacity, SOH-C), which decreases more and more over the course of the battery service life. A degree of aging of the device battery (temporal change in the aging state) depends on an individual load on the device battery, i.e., in the case of vehicle batteries of motor vehicles, on the usage behavior of a driver, external ambient conditions and on the type of vehicle battery.

In order to monitor device batteries from a plurality of devices, operating variable data are typically continuously acquired and transmitted in block fashion to a central processing unit external to the device as operating variable curves. To evaluate the operating variable data, especially in physical or electrochemical battery models based on differential equations, the operating variable data are sampled as curves with a comparatively high temporal resolution (sampling rates) of between 1 and 100 Hz, for example, and a battery state is determined from this using a time integration method.

An electrochemical battery model based on a differential equation system with a plurality of non-linear differential equations can be used to evaluate the operating variable data, in particular to determine battery states that determine the aging state. The operating variable data enables modeling of a current battery state using a time integration method. Such electrochemical battery models are known, for example, from the publications US 2016/023566, US 2016/023567, and US 2020/150185.

Providing the operating variable curves in the central processing unit enables the electrochemical battery model to be used and adapted for a plurality of device batteries with similar battery cells or with cells of similar cell chemistry. The calculation of the battery states using the differential equation system is computationally complex, so that by outsourcing the calculation to the central processing unit, the computing load in the device's internal computing devices can be reduced.

In battery-powered technical devices, the proper functioning of the device battery used must be regularly monitored for faults for safety reasons, especially at high energy densities. If a battery cell, a unit consisting of multiple battery cells or the entire device battery fails, the technical device can become inoperable, depending on the fault that has occurred and, under some circumstances, the safety of the technical device and of the user can be compromised in the event of malfunctions leading to a severe temperature increase.

However, due to rule-based anomaly detection, faults in device batteries have so far only been detected when applied fault threshold values for operating variables, such as the cell voltage, a module temperature, a current value or a state of charge value and an aging state value, are exceeded or not reached.

Publication DE102019208372A1 discloses a computer-implemented method for detecting an anomaly in a technical system, with the following steps: Acquisition of an operating variable vector which indicates an operating state of the technical system and comprises a number of operating state variables, wherein the operating state variables comprise at least one ambient state variable which indicates an ambient condition in which the technical system is operated, and system state variables indicating internal system states of the technical system; providing an ambient state model and an anomaly detection model, wherein the ambient state model indicates a verifiability of the operating variable vector with respect to the presence of an anomaly using the anomaly detection model, depending on at least one of the environmental state variables, and wherein the anomaly detection model indicates the presence of an expected anomaly dependent on the operating variable vector, signaling a presence of an anomaly or a non-anomaly dependent on an evaluation of the at least one ambient state variable of the operating variable vector using the ambient state model and dependent on an evaluation of the operating variable vector dependent on the anomaly detection model.

Furthermore, the publication K. Park, Y. Choi, W. J. Choi, H.-Y. Ryu und H. Kim, “LSTM-Based Battery Remaining Useful Life Prediction With Multi-Channel Charging Profiles,” in IEEE Access, vol. 8, pp. 20786-20798, 2020, the prediction of the remaining service life of a battery using LSTM models for different charging profiles.

### SUMMARY

According to the disclosure, there is provided a method for diagnosing a device battery of a technical device having one or more battery cells as well as an apparatus and a battery system. Further embodiments are also specified herein.

According to a first aspect, a method for monitoring a device battery for predictive detection of a fault in a device battery in a technical device is provided, comprising the following steps:
provision of a historical temporal operating variable curve of several operating variables of a specific device battery;
provision of a predicted temporal operating variable curve depending on a usage pattern model which is designed to be dependent on a usage behavior characterizing a type of use of the appliance battery
determining a time series of input variable vectors, each with elements comprising one or more operating variables and/or one or more variables derived therefrom for a time step, wherein the time series comprises time steps from the historical and predicted operating variable curves;

Evaluating a data-based anomaly prediction model comprising a data-based time series transformer model and a data-based prediction model, wherein the anomaly prediction model is trained as a classification model based on training data sets, each of which assigns to a time series of input variable vectors a probability of occurrence of a certain fault of the device battery after a certain period of time after the last time step of the time series of the input variable vectors,

Predictive detection of the occurrence of a certain device battery fault after a certain period of time based on an evaluation of the anomaly prediction model depending on the time series of the input variable vectors.

While the autoencoder-based approaches commonly used for anomaly detection are able to classify a current battery state as normal or anomalous, a reliable prediction of when a failure event is likely to occur in the future is not possible. However, safety-critical events, such as a thermal runaway event or a total failure of the device battery (sudden death), are announced in advance by battery states, so that it should generally be possible to predict such critical events.

Furthermore, the expected future use of the device battery plays an important role for a possible failure of the device battery, so that it should also be appropriately taken into account in the predictive diagnosis of the device battery.

The above transformer model-based method for predictive detection of an anomaly in a device battery can be provided in a central processing unit external to the device, which is in communication with a plurality of device batteries in order to evaluate operating variable curves of these device batteries in an appropriate manner for anomaly detection.

Transformer models are known, for example, from Qingsong Wen et al, “Transformers in Time Series: A Survey”, arXiv:2202.07125.

Transformer models are usually used in the field of speech recognition. They are based on a multi-head self-attention mechanism in which each input variable vector in a time series of input variable vectors is compared with every other input variable vector in the time series to learn dynamic contextual information between the input variable vectors at different points in time in the form of an evaluation measure or score. Compared to recurrent neural networks, especially LSTMs, transformer models have the advantage that they are also suitable for predicting states for more distant prediction horizons and that a memory of arbitrarily long past points in time is possible and part of the concept. This is relevant, for example, if the battery or an individual cell has been operated by the BMS in an unfavorable load or usage range, which has a long-term effect on the state of health or can influence the probability of an anomaly. These effects are thus acquired and mapped by transformer modeling and made usable for predictive diagnostics.

For capacity reasons, the internal battery state of the device batteries of a plurality of devices is determined in a central processing unit external to the device. For this purpose, the devices transmit temporal operating variable curves of the device batteries in the form of time series of operating variables, such as battery current, battery temperature, charge state and/or battery voltage, to the central processing unit, wherein a current electrochemical internal battery state and/or aging state is determined in the central processing unit. By evaluating the operating variable curves, a device-specific internal battery state and, if necessary, other variables, such as an aging state, can be calculated/determined based on an electrochemical battery model provided for the corresponding battery type of the device battery. The evaluation can be based on the entire device battery, on individual battery cells or units/modules consisting of multiple battery cells.

The electrochemical battery model comprises a differential equation system which, based on differential equations parameterized via model parameters, models internal battery states, in particular equilibrium states and, if applicable, kinetic states, using a time integration method and provides a relationship between operating variables of the battery cells of the device battery, namely a battery current, a battery voltage, a battery temperature and a state of charge of the device battery. Such electrochemical battery models are known, for example, from the publications US 2016/023,566, US 2016/023,567 and US 2020/150,185. The aging state of the respective device battery can be approximately determined as a linear combination of the internal states. The electrochemical battery model can be evaluated in the central processing unit or in a control device for an individual device battery in order to determine the internal battery states.

Model parameters of the electrochemical battery model can be fitted or parameterized (adaptation of the model parameters by minimizing the fault squares) in the central processing unit based on operating variable curves of a plurality of device batteries of the same type within a limited period of time acquired during idle phases (a few minutes to a few hours), wherein electrochemical, equilibrium parameters, kinetic model parameters can be derived, which can comprise, for example, electrolyte concentrations, response rates, layer thicknesses, porosity, etc. The parameterization can be based on a highly accurate measurement of the aging state of the device batteries.

Furthermore, one or more model parameters of a battery model can be fitted based on the operating variable curves, which can also indicate a battery state. Furthermore, the temporal operating variable curves can be aggregated into operating features as statistical or accumulated variables in order to characterize the cyclical load on the device battery.

For example, an aging state model can be used to determine the aging state of the device battery based on the operating variable curves.

In the case of device batteries, the aging state (state of health, SOH) is the key variable to indicate a remaining battery capacity or remaining battery charge. The aging state represents a measure of the aging of the device battery. In the case of a device battery or a battery module or a battery cell, the aging state can be indicated as a capacity retention ratio (SOH-C). The capacity retention ratio SOH-C, i.e., the capacity-based aging state, is indicated as the ratio of the measured instantaneous capacity relative to an initial capacity of the fully-charged battery, and decreases with increased aging. Alternatively, the aging state can be indicated as an increase in internal resistance (SOH-R) relative to an internal resistance at the start of the service life of the device battery. The relative change in the internal resistance SOH-R increases with increasing aging of the battery.

The aging state model can be evaluated in the central processing unit to determine an aging state for an individual device battery. For example, the current aging state can be determined using a physical aging model, which is a form of the electrochemical battery model and can be parameterized accordingly. The physical aging model corresponds to a system of differential equations and is evaluated using a time integration method.

To improve the accuracy of the aging state model, it can be provided in the form of a hybrid aging state model, i.e. a combination of the physical aging model and a data-based correction model. In a hybrid aging state model, a physical aging state can be determined using the physical or electrochemical aging model and a correction value can be applied to it, which results from the data-based correction model, in particular by addition or multiplication. As described above, the physical aging model is based on electrochemical model equations that characterize electrochemical states of a non-linear differential equation system, calculate them continuously and map them to the physical aging state as SOH-C and/or SOH-R for output. The calculations can typically be performed in the cloud, e.g. once a week.

Furthermore, the correction model of the hybrid data-based aging state model can be designed with a probabilistic or artificial intelligence-based regression model, in particular a Gaussian process model, and can be trained to correct the aging state obtained by the physical aging model. For this purpose, there are consequently a data-based correction model of the aging state for correcting the SOH-C and/or at least one further model for correcting the SOH-R. Possible alternatives to the Gaussian process are further supervised learning methods, such as those based on a random forest model, an AdaBoost model, a support vector machine, or a Bayesian neural network.

The correction model can use operating features as input variables, which have been determined from the operating variable curves using feature extraction or feature extraction methods, wherein the features or characteristics are calculated using signal processing operations. The operating features assigned to an operating variable curve define an operating feature point for the energy storage system in question, which maps the load state due to cyclical operation (cyclical aging) and the calendar aging of the energy storage system (elapsed period of time since commissioning or start of service life).

The operating features can comprise cumulative load-based features or aggregated features and/or statistical variables determined over the entire service life to date.

In particular, features from histogram data that were created from the curves of the operating variables can be determined as operating features. For example, histograms with respect to the battery current over the battery temperature and the charging state of the vehicle battery, a histogram of the battery temperature over the charging state of the vehicle battery, a histogram of the charging current over a battery temperature, and a histogram of a discharging current over the battery temperature can be created. Furthermore, the accumulated total charge (Ah), an average capacity increase during a charging process (in particular for charging processes in which the charge increase is above a threshold fraction [e.g., 20% ASOC] of the total battery capacity), the charging capacity as well as an extreme value (e.g., a local maximum) of the smoothed differential capacity during a measured charging process with sufficiently large stroke of the charging state (smoothed curve of dQ/dU: charge change divided by change in the battery voltage) or the accumulated driving power, respectively since the initial operation of the device battery, can be taken into account as operating features. Further operating features can correspond to a local extreme value of the spectral kurtosis, evaluated on a charging process for current or voltage signal, one or more coefficients of a wavelet transform and/or one or more coefficients of the Fourier transform, each evaluated for a charging process for a current or voltage signal or a transformed spectral value assigned to a defined frequency band.

Operating features can thus be derived from histograms with regard to operating variables. From this, feature engineering or feature extraction methods can be used to extract operating features such as the mean value, the standard deviations of the histograms and multidimensional statistical values such as mean value, median, minimum, maximum, moments of the distribution and the like.

Furthermore, a battery performance model based on the operating variable curves can be evaluated in the central processing unit in order to provide equivalent circuit diagram parameters, such as internal resistances and a capacity of a battery equivalent circuit diagram.

Furthermore, the one or more derived variables can comprise one or more operating features derived from the operating variable curves and/or an aging state derived from the operating variable curves and/or one or more internal battery states derived from the operating variable curves and/or one or more model parameters of a battery model fitted to the operating variable curves.

To take into account future use of the appliance battery under consideration, an operating variable curve can be predicted based on an evaluation of a historical usage pattern. The historical usage pattern can be determined by evaluating the historically observed operating variable curves and contain information that can be used to generate an “artificial” predicted operating variable curve for a future period based on heuristics, probabilities or data. This predicted operating variable curve corresponds to a realistically possible operating variable curve that corresponds to a load on the device battery to which the device battery has already been exposed in the immediate past. Alternatively, by changing the usage pattern, an “artificial” predicted operating variable curve can be generated, which could occur, for example, when a user whose usage behavior is already known changes. This enables anomaly prediction even at the point in time of a user change.

A data-based anomaly prediction model is trained or evaluated on the basis of the operating variable curves provided as time series of the battery current, battery voltage, state of charge and battery temperature, the predicted operating variable curves, and a curve of one or more variables derived from these.

The curves refer to specified evaluation points in time of the time series of the provided and predicted operating variable curves. The evaluation points in time can be determined immediately after the last point in time of the time series of the predicted operating variable curves or with a time lag.

The curves of the derived variables can comprise one or more of the following, which are derived from the historical and predicted operating variable curves: an aging state derived using the aging state model (historical and predicted); one or more internal battery states determined from an electrochemical aging model at the specified evaluation points of time of the time series of the provided and predicted operating variable curves as a result of the evaluation by the differential equation system; and one or more operating features, which in a given case are already determined for the correction model of the above hybrid aging state model using a feature extraction block as aggregated variables or histogram-based variables.

The anomaly prediction model is designed to map a time series of input variable vectors to a probability of a specific anomaly event at a future point in time. The time series comprises a historical fraction and a predicted fraction. The input variable vectors of the time series each represent an evaluation point in time and are each composed of the operating variables or aggregated operating variables (if these are available in a higher resolution than the time series) at the relevant evaluation point in time and the variables derived from them, such as the operating features, the aging state derived from them and/or the internal battery states derived from them, as described above.

The anomaly prediction model has a time series transformer model that maps the time series of the input variable vectors {xₜ₁, xₜ₂, . . . xₜₙ}^{T} of past time steps to a resulting set of state variable vectors {z₁, . . . , z_{N}}^{T}. The resulting set of state variable vectors {z₁, . . . , z_{N}}^{T} is converted into a probability of a critical event at a future point in time using the data-based prediction model.

It can be provided that the time series transformer model comprises a pre-processing block to provide a set of first state variable vectors, wherein the set of first state variable vectors is processed by a serial sequence of multi-head self-attention modules into a resultant set of further state variable vectors, wherein the resultant set of further state variable vectors is assigned a fault class in the prediction block, wherein the fault class indicates the fault type and the period of time after which a fault of the fault type will occur.

The input variable vectors {xₜ₁, xₜ₂, . . . xₜₙ} for the considered time steps t₁ . . . t_{N} are now encoded a first set of state variable vectors z⁰ for each time step/evaluation point in time.

This is achieved by a time feature encoder and a data feature encoder. The time feature encoder can simply specify a relative time lag between successive time steps back in time, such as for example fₜᵢₘₑ(t_{N})=0, fₜᵢₘₑ (t_{N-1})=t_{N}−t_{N-1} etc. This is particularly important for varying durations of the time steps between the input variable vectors of the time series of the input variable vectors.

Furthermore, a neural network can be provided for the data feature encoder in order to perform feature extraction for data features f_{data}. This results in a state vector z_{1 . . . N}⁰=[fₜᵢₘₑ, f_{data}]^{T} for each time step t₁ . . . t_{N}. This allows the dimensionality of the state variable vector z to be changed, thus reducing the number of parameters of the entire network.

After the initial creation of the first set of state vectors z_{1 . . . N}⁰, further processing is carried out by one or more serially arranged multi-head self-attention modules. Each input vector and output vector of the multi-head self-attention modules have the same dimensions, so that an arbitrary depth and number of serial multi-head self-attention modules can be provided.

A multi-head self-attention module has M parallel self-attention units (heads). Each self-attention unit can process different features of the time series of the input variable vectors. Since the M parallel self-attention units each provide an output vector that has the same dimensionality as the corresponding input variable vector, the output vectors of the multiple self-attention units can be summarized to a subsequent state variable vector, usually using a data-based model such as a neural network.

Each self-attention unit processes the state variable vector z in a known manner with a query key-value triplet. The self-attention score is then calculated, which indicates the extent to which each state variable vector at a particular time step depends on another state vector at another time step.

Since the sequence of state variable vectors (their index) is arranged according to the time steps t1 . . . tN, masking can be used so that the state variable vector of one time step cannot be related to a state variable vector of a future time step. Thus, the resulting self-attention score matrix (for the scores of each state variable vector to another state variable vector) is masked using a masking function that (zᵢ to zⱼ)=0 ∀j>i. The self-attention score matrix S is calculated as

S=softmax(QK^{T}+Mask)

The matrices Q, K, and V are determined from the input variable vectors of the time series. In general, the matrix Q encodes which other input variable vector the respective input variable vector refers to and the matrix K encodes what the input variable vector represents. The self-attention score S is obtained by multiplication. The matrix Q is determined as Q=T_q*Z in the form of a matrix of dimension dim×N. dim corresponds to the size of the input-side state variable vector and N to the length of the time series. T_q corresponds to learned model parameters of the variable dim×dim_input and Z corresponds to a matrix of the input variable vectors x with the dimension dim_input×N.

Similarly, the matrix K is calculated as K=T_k*Z in the form of a matrix of the dimension of size dim×N. dim corresponds to the variable of the input-side state variable vector and N to the length of the time series. T_k corresponds to learned model parameters of the variable dim×dim_input and Z corresponds to a matrix of the input variable vectors x with the dimension dim_input×N. The matrix V is determined in the same way.

The model parameters T_q, T_k, T_v are trained during the training of the anomaly prediction model.

A training data set is created, for example, for the device batteries in which a fault of a fault type to be predicted has occurred, such as sudden death, thermal runaway, premature aging or similar. The training data set assigns the fault to a fault class that specifies which fault type the fault corresponds to and when it is likely to occur according to the last input variable vector considered. The time series of the input variable vectors is selected in such a way that the most recent point in time in the time series precedes the point in time of the fault event by the period of time assigned to the fault class.

The time series of the input variable vectors of the anomaly prediction model are used for training, which predicts the expected probability of a fault event for a specific future event according to a fault class defined in this way. The prediction model can be designed as a conventional classification model for this purpose.

Each fault class of the model output of the prediction model is assigned to a specific error type and a period of time at which a fault of the specific fault type is expected to occur after a recent point in time of the time series of the input variable vectors. For this purpose, anomaly events of device batteries from the field are used as training data, and the corresponding probability of occurrence for an anomaly, i.e. a specific fault type, is labeled 1, while the time series of the input variable vectors considered for this training data set represents a time series whose end point in time corresponds to a point in time that precedes the detected occurrence of the fault of the specific fault type by the period of time assigned to the corresponding fault class.

A binary cross-entropy loss function can be used as a loss function for training:

L=−Σᵢ^{B}Σₜyₜ log p(yₜ)+(1−yₜ)log(1−p(yₜ)).
wherein yₜ corresponds to a class label of the fault class and B is the number of training data records. The labeled data can comprise: the capacity-related aging state (SOHC), the resistance change-related aging state (SOHR), as well as variables resulting from an electrochemical battery model such as a volume fraction of the anode (volume fraction anode), a volume fraction of the cathode (volume fraction cathode), a set of cyclizable lithium, a response rate, a diffusion coefficient, a layer resistance, and a contact resistance.

In particular, the problem can be defined multivariate or comprise multiple output variables.

Training can be based on training data sets where an anomaly event has been detected or on training data where no anomaly event has been detected. The corresponding label of all fault classes is then set to “0”. Different numbers of training data sets for anomaly events and regular battery function can be taken into account by suitable weighting factors in the loss function.

After training the anomaly prediction model, the corresponding model parameters can be transferred to the technical device so that the anomaly prediction model can be executed there in order to be able to immediately detect an anomaly in the corresponding device battery predictively according to a predefined prediction horizon. For this purpose, it can be provided that models for generating artificial predicted operating variable curves and for determining an aging state using time series integration are also implemented in the technical device depending on the provided and predicted operating variable curves, so that predictive anomaly detection independent of the central processing unit is possible.

Alternatively, the anomaly prediction model can also be executed in the central processing unit and detected predictive anomalies can be signaled to the technical device.

It can be provided that an occurrence of a certain fault of the device battery is detected after a certain period of time depending on the time series of the input variable vectors if the evaluation of the anomaly prediction model results in a probability for the corresponding fault class above a predetermined threshold value, wherein the occurrence of the certain fault is signaled when it is detected, in particular by issuing a warning to a user.

If an evaluation using a time series of input variable vectors determines that an anomaly, i.e. a certain fault, will occur with a certain probability at a certain point in time in the future, a warning can be issued to the users of the technical device. If a safety-critical anomaly is detected on the basis of the fault type to which the fault class is assigned, this can be communicated externally to the device and/or the device battery can be brought into a safe state, for example by rapid discharging in order to dissipate the energy stored in the battery.

The anomaly prediction model can be retrained or retrained at regular points in time, e.g. every two months. In particular, the anomaly prediction model can be retrained if a new anomaly event has occurred in one of several device batteries connected to the central processing unit.

### BRIEF DESCRIPTION OF THE DRAWINGS

Embodiments are explained in greater detail hereinafter by means of the accompanying drawings. Here:

FIG. 1 shows a schematic representation of a system for providing driver- and vehicle-specific operating variables for detecting a predicted anomaly of a vehicle battery in a central processing unit;

FIG. 2 shows a schematic representation of a functional structure of a system for predictive detection of a fault in a device battery; and

FIG. 3 shows a schematic representation of the functional structure of a self-attention unit.

### DETAILED DESCRIPTION

In the following, the method according to the disclosure is described using vehicle batteries as device batteries in a plurality of motor vehicles as similar devices. For this purpose, one or more electrochemical battery models are evaluated and parameterized in the central processing unit based on operating variable curves. An anomaly prediction model is trained in the central processing unit and evaluated there or the model parameters of the anomaly prediction model are transferred to the control devices of the vehicles in the vehicle fleet so that an anomaly can be detected there by continuously evaluating the anomaly prediction model.

The above example is representative of a plurality of stationary or mobile devices with a network-independent energy supply, such as vehicles (electric vehicles, pedelecs, etc.), systems, machine tools, household appliances, IOT devices, and the like, which are connected via a corresponding communication connection (e.g., LAN, Internet) to an external central processing unit (cloud).

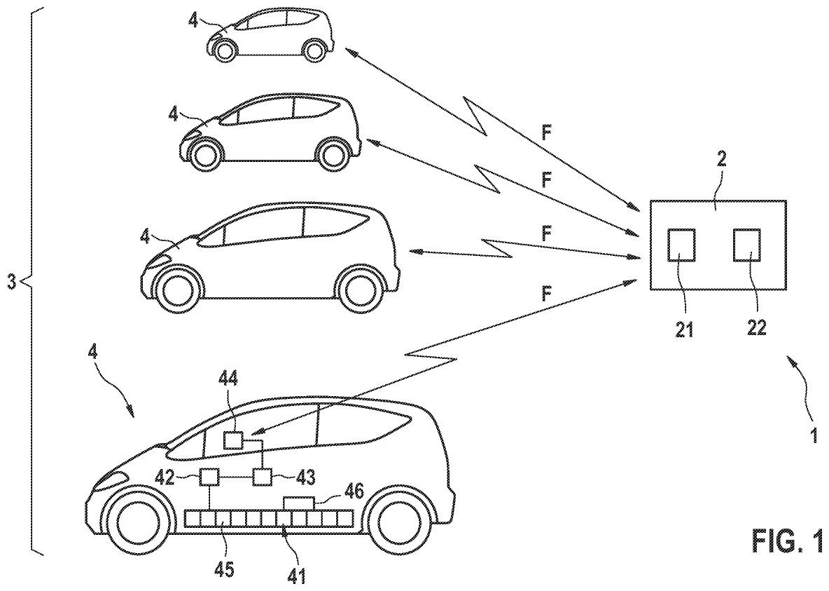

FIG. 1 shows a system 1 for collecting fleet data in a central processing unit 2 for creating, operating and evaluating an electrochemical battery model and a battery performance model, each for modeling internal battery states of the vehicle battery and an aging state model for determining the aging state of a vehicle battery in a motor vehicle.

FIG. 1 shows a vehicle fleet 3 with several motor vehicles 4. One of the motor vehicles 4 is shown in greater detail in FIG. 1. The motor vehicles 4 each have a vehicle battery 41 with battery cells 45, an electric drive motor 42 and a control unit 43. The control unit 43 is connected to a communication device 44, which is suitable for transmitting data between the respective motor vehicle 4 and a central processing unit 2 (a so-called cloud).

In particular, the control unit 43 is designed to use a battery management system 46 to acquire operating variables of the vehicle battery 41 with a high temporal resolution, such as between 1 and 50 Hz, e.g. 10 Hz, and to transmit these to the central processing unit 2 via the communication device 44.

The motor vehicles 4 transmit to the central processing unit 2 the operating variables F, which at least indicate variables that influence the aging state of the vehicle battery 41 or are influenced by it, and which are required for determining the internal battery states, an aging state, a parameterization of an electrochemical battery model. In the case of a vehicle battery, the operating variables F can indicate an instantaneous battery current, an instantaneous battery voltage, an instantaneous battery temperature and an instantaneous state of charge (SOC), at the pack, module and/or cell level. The operating variables Fare acquired in a fast chronological grid from 0.1 Hz to 50 Hz as operating variable curves, and can be transmitted regularly to the central processing unit 2 in uncompressed and/or compressed form. For example, by using compression algorithms, the chronological series can be transmitted to the central processing unit 2 in blocks at intervals of 10 min to several hours in order to minimize data traffic to the central processing unit 2.

The central processing unit 2 has a data processing unit 21, in which part of the method described below can be carried out, and a database 22 for storing data points, model parameters, states and the like.

The central processing unit 2 is designed to receive the operating variable curves F. The central processing unit 2 can determine a current aging state, e.g. using an aging state model, one or more internal battery states, e.g. using an electrochemical battery model and/or as model parameters of a battery performance model, and/or one or more operating features as aggregated or accumulated or histogram-based variables as derived variables from the operating variable curves for the respective vehicle battery 41 in a manner known per se.

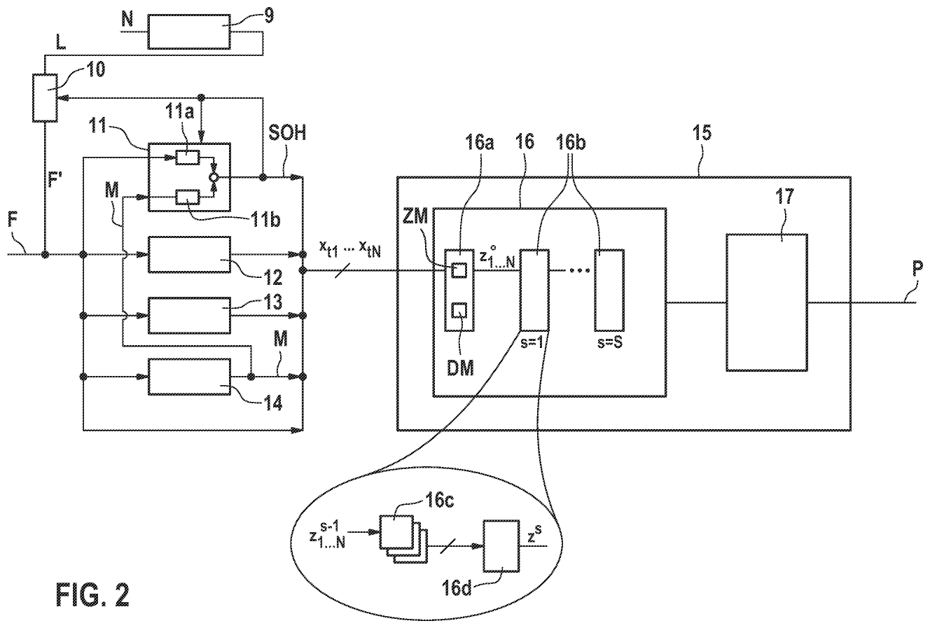

FIG. 2 shows a schematic example of the functional structure of a system 10 for predictive detection of an anomaly in a vehicle battery 45. The system is implemented in the central processing unit 2 as software or hardware and evaluates time series of operating variables that indicate operating variable curves, such as battery current, battery voltage, state of charge and battery temperature.

The temporal operating variable curves F are received by the vehicles 4. In addition, predicted operating variable curves F′ can be determined based on a usage pattern model 9. The usage pattern model 9 can predict temporal load variable curves L, in particular the battery current and the battery temperature, in the manner described below. The predicted load variable curves can be supplemented with a known battery performance model or a dynamic model 10 by further predicted operating variable curves, in particular curves of the battery voltage and the state of charge, which are determined from the predicted load variable curves L of the battery current and the battery temperature. The state of charge can be determined, for example, by charge integration of outflowing and inflowing charge by integrating current flows of the battery current.

The battery performance model 10 or the dynamic model can be designed in various ways, such as an equivalent circuit model (for an electrical equivalent circuit), an electrochemical model, a single-particle model of battery cells or the like. In particular, the battery performance model 10 can correspond to an electrochemical battery model that models equilibrium states and calibrates itself to cell voltages in idle phases in order to generate a battery current and state of charge from a battery voltage. Alternatively, the battery performance model 10 can be a battery performance model for characterizing the system transfer function, wherein the non-linearity of the current strength is calculated out using Butler-Volmer tuning.

The generation of the artificial predicted operating variable curves F′ from the predicted curves of the load variables L in the battery performance model 10 can be carried out as a function of an determined aging state SOH of the vehicle battery 41, which causes the battery performance model 10 to be updated specifically with regard to its parameters or alternatively its states. The transmission behavior of the battery performance model 10 thus changes depending on the aging state SOH of the vehicle battery 41. Typically, this parameter update takes place once per (simulated) month during a simulation or prediction.

The aging state SOH is taken into account by updating parameters and/or states of the battery performance model 10 on the basis of the calculated modeled aging state SOH.

A usage pattern model 9 is used to generate the curves of the load variables L for the prediction of the aging state. The usage pattern model 9 converts predetermined usage patterns N into curves of load variables L that reflect the load on the energy storage system to which the vehicle battery 41 is exposed during the usage and operating mode specified by the usage pattern. The usage patterns N thus lead to the output of a temporal curve of a battery current I and a battery temperature T as load variables L by the usage pattern model 9, which is used to complete the set of operating variables with the curves of the battery voltage U and the state of charge SOC using the dynamic model 10 in order to generate the artificially generated predicted curves of the operating variables F.

The usage patterns N can be defined by usage parameters which are learned from fleet data on a vehicle-specific basis by the usage pattern model 9, preferably with the aid of data-based methods, and are used to simulate the usage behavior of a user with regard to the relevant vehicle battery 41.

The usage pattern model 9 can be designed as a recurrent neural network, such as an LST or GRU, in particular as a Bayesian LSTM network, and can be trained based on curves of load variables or operating variables F, which indicate a type of usage or a load or stress on the vehicle battery 41. The curves of load variables L and operating variables F to be taken into account should be based on a period of the same type of use and the same operating mode of the vehicle battery 41.

The usage parameters that specify the usage pattern N then correspond to the model parameters of the usage pattern model 9, i.e. in the case of a neural network, the weights and bias values of the individual neurons. Furthermore, prior and posterior distributions as well as probabilities conditioned on observations according to Bayes' theorem can be considered as relevant parameters.

The usage patterns N can result from training the usage pattern model 9 based on known temporal curves of the load variables and/or the operating variables F of a specific vehicle 4 (vehicle-specific or user-specific) with regard to their calendar reference. This means that the usage pattern model 9 is trained on the input side with a calendar time specification and on the output side with the load variables (current, temperature, preferably as a time series) and/or the operating variables F in a manner known for recurrent neural networks. By specifying a calendar time, such as the date and a time, an artificial curve of the load variables L and/or the operating variables F can be generated. The calendar time information can also contain the day of the week, the month and information about public holidays and can take seasonal factors into account, particularly through feature engineering.

The usage pattern model 9 can thus be formed directly from raw data on the curves of the load variables L and/or the operating variables F. Typical patterns of the current profile for the vehicle battery 41, e.g. due to recurring commuter routes, typical idle and rest periods, are thus detected and made reproducible.

Alternatively, the usage parameters N can also be load parameters which, for example, characterize the type of use and/or operating mode of the vehicle battery 41 and can correspond to statistically acquired variables. Usage patterns can, for example, be derived as aggregated variables from a battery current curve, a battery temperature curve and distributions of times of use of the vehicle battery, charging and idle states.

The usage pattern N can also indicate ambient conditions and a periodic load curve in particular. The ambient conditions can, for example, be derived from a climate table or temperature table, and indicate a battery temperature curve within a day-night rhythm, for the seasons and the like, preferably with the aid of GPS-dependent weather data from the central processing unit (cloud). For this purpose, the usage pattern model 9 can be trained and used with an ambient temperature curve in addition to the calendar time specification. Preferably, predictions of ambient temperature curves from the determining of a geoposition, e.g. using GPS, can be taken into account in the prediction of the artificial operating variable curves.

The temperature curve can be derived from an average temperature in the immediate past, such as a month, which can be predicted using seasonal fluctuations derived from a climate table. The climate table can be derived from a location (geoposition) of the vehicle (vehicle location: location of the most frequently determined vehicle position). The usage pattern model 9 thus provides for a mapping of the calendar time and the temperature curve to the curves of the load variables and/or the operating variables F as input variables and is also trained accordingly.

In addition, the usage pattern model 9 can be operated depending on the modeled aging state SOH. This makes it possible to take into account the fact that a driver with an aged vehicle battery is more likely to have to charge three times a week or replace the battery with a fully charged one instead of just twice, as was initially the case, in order to cover the desired distance.

The usage patterns N are trained and specified for each individual vehicle and characterize the type of use and operation or the usage and operating behavior of the respective vehicle batteries 45.

Time series of input variable vectors xₜ₁ . . . x_{tN} at discrete time steps t₁ . . . t_{N} are formed from the historical operating variable curves F and the predicted operating variable curves F′. The time period t₁ . . . t_{N} comprises the historical trends in operating variable curves and the predicted trends in operating variable curves. The historical and predicted operating variable curves F, F′ can be pre-processed using one or more battery models and feature extraction models to provide an aging state and/or one or more internal battery states and/or one or more operating features. The aging state SOH, which can comprise one or more internal battery states, the one or more operating features and one or more of the operating variables at a time step, can form the input variable vector x_{t1 . . . tN} at a respective evaluation point in time/time step t₁ . . . t_{N}.

The battery models can comprise one or more of the following models: an aging state model 11, an electrochemical battery model 12 and an electrochemical performance model 13.

For example, the aging state model 11, which is partially data-based as a hybrid model, can be implemented in the central processing unit 2. The aging state model 11 can be used regularly, i.e. e.g. after expiry of the respective evaluation period of time, in order to determine the current aging states of the relevant vehicle battery 41 of the assigned vehicle fleet 3 based on the temporal curves of the operating variables (in each case since commissioning of the respective vehicle battery or starting from a state of known battery states) and operating features M determined therefrom.

The aging state model 11 comprises a physical aging model 11a and a correction model 11b. The physical aging model 11a is a non-linear mathematical model based on differential equations and calculates a physical aging state using time integration methods. The evaluation of the physical aging model 11a of the aging state model 11 with the historical and predicted operating variable curves F, F′, in particular since the start of the service life of the vehicle battery 41, results in an internal state of the system of equations of the physical differential equations which corresponds to a physical internal state of the vehicle battery 41. Since the physical aging model 11a is based on physical and electrochemical laws, the model parameters of the physical aging model are variables that specify physical properties.

The time series of the historical and predicted operating variables F, F′ of the vehicle battery 41 are thus incorporated directly into the physical aging state model 11a, which is preferably designed as an electrochemical model and takes into account corresponding internal electrochemical battery states, such as layer thicknesses (e.g. SEI thickness), change in cyclable lithium due to anode/cathode side reactions, rapid consumption of electrolytes, slow consumption of electrolytes, loss of active material in the anode, loss of active material in the cathode, etc., using non-linear data . . . , are modeled using non-linear differential equations and a multi-dimensional state vector. The physical aging model therefore corresponds to a variant of an electrochemical battery model.

However, the model values for the physical aging state provided by the physical aging model 11a are inaccurate in certain situations, and it can therefore be necessary to correct them with a correction variable. The correction variable is provided by the data-based correction model 11b, which is trained using training data sets from the vehicles 4 in the vehicle fleet 3 and/or using laboratory data. In particular, the physical aging state and the correction variable can be added or otherwise multiplied (not shown) in a summation block in order to output an aging state as a state variable for the vehicle battery.

The correction model 11b receives operating features M on the input side, which are determined from the curves of the historical and predicted operating variables F, F′ using a feature extraction block 14 and can also comprise one or more of the internal electrochemical states of the differential equation system of the physical model. Furthermore, the correction model 11b can receive the physical aging state obtained from the physical aging model 11a on the input side.

The operating features M of the current evaluation period can be generated in a feature extraction block 14 based on the temporal historical and predicted operating variable curves F, F′. The operating features M also include the internal states from the state vector of the electrochemical physical aging model 11a and, advantageously, the physical aging state.

The feature extraction model 14 makes it possible to aggregate the historical and predicted operating variable curves F, F′ into operating features, as described above in relation to the hybrid aging state model, for example. In particular, the operating features can comprise state features and histogram-based features.

The operating features M can, for example, comprise features related to an evaluation period and/or features accumulated over an evaluation period and/or statistical variables determined over the entire service life to date. In particular, the operating features can include, for example: electrochemical states, such as SEI layer thickness, change of cyclable lithium due to anode/cathode side reactions, rapid absorption of electrolyte solvents, slow absorption of electrolyte solvents, lithium deposition, loss of active anode material and loss of active cathode material, information on impedances or the internal resistances, histogram features, such as temperature over state of charge, charging current over temperature and discharging current over temperature, in particular multi-dimensional histogram data with respect to the battery temperature distribution over the state of charge, the charging current distribution over the temperature and/or the discharging current distribution over the temperature, the current flow rate in ampere-hours, the accumulated total charge (Ah), an average increase in capacity during a charging operation (in particular for charging operations in which the charge increase is above a threshold fraction [e.g., 20% ΔSOC] of the total battery capacity), the charging capacity as well as an extreme value (e.g., maximum) of the differential capacity during a measured charging operation with sufficiently large delta of the state of charge (smoothed curve of dQ/dU: charge change divided by change in the battery voltage) or the accumulated driving power. These variables are preferably converted in such a way that they best characterize the real usage behavior and are standardized in the feature space. The operating features M can be used in full or only partially for the correction model 11b.

Training of the hybrid aging state model is carried out in the central processing unit 2. For this purpose, training data sets are defined that assign historical operating variable curves F to an empirically or model-based determined aging state as a label. These are used to fit parameters of the physical aging model and to train the correction model on the remaining residual.

An aging state can be determined as a label in a manner known per se by evaluating the operating variable curves F with an additional aging model in the vehicle or in the central processing unit 2 under defined load and ambient conditions of a label generation, such as in a workshop, on a test bench or a diagnostic or label generation mode, which represents an operating mode and guarantees compliance with predetermined operating conditions of the vehicle battery, such as constant temperature, constant current and the like. For example, the aging state can be determined by means of coloumb counting to determine the remaining total capacity of the vehicle battery.

Furthermore, an electrochemical battery model can be used in the central processing unit 2 to model internal battery states. The electrochemical battery model is based on a system of differential equations with a plurality of non-linear differential equations. The historical and predicted operating variable curves F, F′ enable a current battery state to be modeled using a time integration method. Such electrochemical battery models are known, for example, from the publications US 2016/023,566, US 2016/023,567 and US 2020/150,185.

Furthermore, a (further) battery performance model 13 can be provided in the form of an electrochemical battery model, which is characterized by its model parameters and models an internal state of the battery cells. The electrochemical battery model is based on electrochemical model equations parameterized by the model parameters, which characterize electrochemical states of a non-linear differential equation system and can be continuously evaluated according to a time integration method. The electrochemical battery performance model generally corresponds to an observer model that assigns a battery current and a battery temperature to a battery voltage with the aim of describing the dynamics of the battery.

The electrochemical battery performance model 13 can be fitted to the operating variable curves during idle phases, e.g. using a least-square method or similar. Based on the battery performance model 13, the aging state of the battery cells can be determined on the basis of the fitted electrochemical model parameters. The electrochemical battery performance model 13 can model battery states and be described by model parameters, in particular equilibrium parameters and kinetic parameters. The model parameters can be re-parameterized at regular intervals by fitting, especially if operating variable curves with a high sampling rate are available for a defined period of at least a few (e.g. three) hours. Such model parameters of the battery performance model 13 can be interpreted as battery states.

The evaluation of the models described above at a particular point in time/time step results in input variables for an anomaly prediction model 15, which comprise one or more of the following variables: the aging state, one or more of the internal battery states of the electrochemical battery model, one or more model parameters of the battery performance model and/or one or more operating features. Furthermore, the input variables of the anomaly prediction model 15 comprise the operating variables of the operating state curves, in particular averaged over the period of time between two successive time steps.

The anomaly prediction model 15 comprises a time series transformer model 16 and a data-based prediction model 17.

The input variables for the anomaly prediction model 15 are provided in the form of a time series {xₜ₁, xₜ₂, . . . x_{tN}} of input variable vectors xₜ₁, xₜ₂, . . . x_{tN} for successive time steps

In the time series transformer model 16, the time series of input variable vectors {xₜ₁, xₜ₂, . . . x_{tN}} is first z_{1 . . . N}⁰ processed into a first set of N state variable vectors in a pre-processing block 16a.

This is achieved by a time feature encoder ZM and a data feature encoder DM. The time feature encoder ZM can simply specify a relative time lag back in time, such as fₜᵢₘₑ (t_{N})=0, fₜᵢₘₑ (t_{N-1})=t_{N}−t_{N-1} etc.

The data feature encoder DM can be provided as a data-based model, e.g. a neural network, to perform feature extraction on data features f_{data}. This can be used to reduce dimensions, for example. For each input variable vector {xₜ₁, xₜ₂, . . . xₜₙ} at each time step t1 . . . tN there is a first state variable vector z_{1 . . . N}⁰=[fₜᵢₘₑ, f_{data}]^{T}. This allows the dimensionality of the state vector z to be changed, thus reducing the number of parameters of the entire network.

This set of first state variable vectors z_{1 . . . N}⁰ is processed serially by one or more (number S) multi-head self-attention modules 16b. Each multi-head self-attention module 16b processes a respective state variable vector of z_{1 . . . N}^{s-1} the s-th stage into an output-side state variable vector z_{1 . . . N}^{s} of the same dimension, so that the multi-head self-attention modules 16b can be strung together in any number S.

Each multi-head self-attention module 16b has M parallel self-attention units 16c, which z_{1 . . . N}^{s-1} take into account the different features of the set of the respective input-side state variable vectors. The input vectors and output vectors for each of the self-attention units 16c have the same dimensionality, which z_{1 . . . N}^{s} can be reduced to the dimension of the state variable vectors using a reduction model 16d in the form of a data-based model, such as a deep neural network.

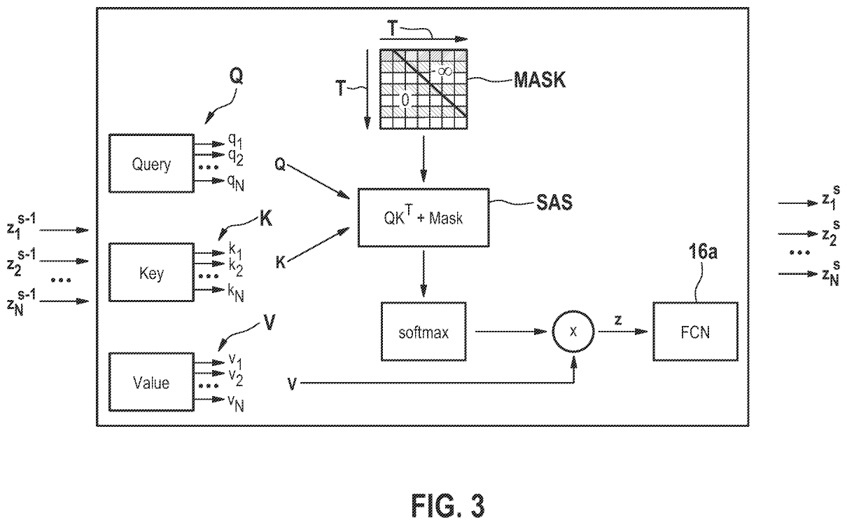

As shown in FIG. 3, each self-attention unit 16c processes the set of state variable vectors z_{1 . . . N}^{s-1} as a matrix Q to obtain a matrix in the form of QK^{T}. The procedure corresponds to one described in the publication Qingsong Wen et al, “Transformers in Time Series: A Survey”, arXiv:2202.07125.

Each self-attention unit 16c processes the state variable vector z_{1 . . . N}^{s-1} in a known manner with a query (Q)-key (K)-value (V) triplet.

The matrices Q, K, and V are determined from the input variable vectors (dimension dim_input) of the time series. In general, the matrix Q encodes which other input variable vector the input variable vector in question refers to, and the matrix K encodes a representation of the input variable vector. The self-attention score S is obtained by multiplication. The matrix Q is determined as Q=T_q*Z in the form of a matrix of dimension dim×N. dim corresponds to the size of the input-side state variable vector and N to the length of the time series. T_q corresponds to learned model parameters of the variable dim×dim_input and Z corresponds to a matrix of the input variable vectors x with the dimension dim_input×N.

Similarly, the matrix K is calculated as K=T_k*Z in the form of a matrix of dimension dim×N. dim corresponds to the size of the input-side state variable vector and N to the length of the time series. T_k corresponds to learned model parameters of the variable dim×dim_input and Z corresponds to a matrix of the input variable vectors x with the dimension dim_input×N.

The matrix V is determined as V=T_v*Z in the form of a matrix of the dimension dim×N. dim corresponds to the size of the input-side state variable vector and N to the length of the time series. T_v corresponds to learned model parameters of the variable dim×dim_input and Z corresponds to a matrix of the input variable vectors x with the dimension dim_input×N.

The model parameters T_q, T_k, T_v are trained during the training of the anomaly prediction model 15.

The self-attention score is then calculated in the form of the self-attention score matrix SAS (N×N matrix), which indicates the extent to which each state variable vector z_{j∈1 . . . N}^{s-1} at a particular time step depends on another state variable vector z_{1 . . . j-1,j+1 . . . N}^{s-1} at another time step.

The resulting matrix is masked for this purpose. For this purpose, masking by a masking matrix MASK is used, which takes into account the elements of the matrix in relation to time steps in such a way that the evaluation measure/score of the current state variable vector cannot depend on future state variable vectors. The corresponding elements of the matrix are assigned −∞.

A softmax function 16e is then applied row by row to the elements of the masked matrix in order to obtain a vector of dimension N.

The resulting Self-Attention-Score-Matrix SAS is weighted by the Value-Matrix V and optionally further processed by a feature extraction model 16f.

These steps correspond to the conventional steps for executing a transformer model, as known, for example, from Qingsong Wen et al, “Transformers in Time Series: A Survey”, arXiv:2202.07125.

The set of state variable vectors z_{j∈1 . . . N}^{S}, which is obtained on the output side of one or more of the multi-head self-attention modules 16b, is now converted into a classification result using a prediction model 17, which gives a prediction of the occurrence of a fault of a certain fault type at a certain point in time in the future.

Once the anomaly prediction model 15 has been created, model parameters can be transmitted to the vehicles 4 so that the anomaly prediction model 15 can be executed there. The model parameters can be updated in the vehicles 4 after each update of the anomaly prediction model 15 in the central processing unit 2.

The evaluation of the anomaly prediction model 15 in the vehicle results in an indication of a failure probability or the probability of occurrence of an anomaly or a fault of a certain fault type at a predetermined point in time in the future by a value of the model output in a fault class. If a probability above a certain threshold value is detected for a certain fault class, a warning can be signaled, for example in the form of a visual or acoustic signal. Alternatively, the vehicle battery 41 can be brought into a safe state if the predicted probability of failure is above the predetermined threshold value and the fault class indicates a critical fault and a short period of time after which the fault is likely to occur.

The training of the anomaly prediction model 15 can generally be based on training data sets. These can comprise training data records for faults that have occurred in the vehicle fleet 3. If a fault has occurred, a “1” is assigned as a label to a fault class that indicates the specific fault type and a period of time after which the specific fault should occur. The label is assigned to a time series of input variable vectors whose last time step precedes the time of occurrence of the fault by the period of time. Furthermore, training data records can be created for correct batteries, i.e. the label “0” is assigned to all fault classes. The anomaly prediction model 15 is trained in a known manner using gradient-based training methods, such as backpropagation.

The anomaly prediction model 15 can be retrained each time one or more new anomalies occur in the vehicle batteries 41 of the vehicles in communication with the central processing unit 2. Independently of this, the anomaly prediction model 15 can also be retrained at regular intervals, such as every six months, in order to take into account new information on battery aging for the entire fleet.

What is claimed is:

1. A method of monitoring a device battery for predictively detecting a fault in the device battery in a technical device, the method comprising:
providing a historical temporal operating variable curve of several operating variables of a specific device battery;
providing a predicted temporal operating variable curve dependent on a usage pattern model, the usage pattern model dependent on a usage behavior characterizing a type of use of the device battery;
determining a time series of input variable vectors each with elements which comprise one or more operating variables and/or one or more variables derived therefrom for a time step, wherein a time series comprises the time steps from the historical and predicted operating variable curves;
evaluating a data-based anomaly prediction model comprising a data-based time series transformer model and a data-based prediction model, the anomaly prediction model trained as a classification model based on training data sets, each of which assigns to a time series of input variable vectors a probability of occurrence of a certain fault of the device battery after a certain period of time after a last time step of the time series of the input variable vectors;
performing predictive detection of an occurrence of a specific fault of the device battery after a specific period of time based on an evaluation of the anomaly prediction model depending on the time series of the input variable vectors.

2. The method according to claim 1, wherein the one or more derived variables comprise:
one or more operating features derived from the historical and predicted operating variable curves,
an aging state derived from the historical and predicted operating variable curves,
one or more internal battery states derived from the historical and predicted operating variable curves, and/or
one or more model parameters of a battery model fitted to the historical and predicted operating variable curves.

3. The method according to claim 1, wherein:
the time series transformer model comprises a pre-processing block to provide a set of first state variable vectors,
the set of first state variable vectors is processed by a serial sequence of multi-head self-attention modules into a resulting set of further state variable vectors,
the resulting set of further state variable vectors is assigned to a fault class in the prediction block, and
the fault class indicates a fault type and the period of time after which a fault of the fault type will occur.

4. The method according to claim 3, wherein in the pre-processing block a time feature of the time series is formed as time lags between the time steps and data features from the respective input variable vector of the respective time step as first state variable vectors.

5. The method according to claim 3, wherein:
at least one of the multi-head self-attention modules comprises a plurality of self-attention units, and
each of the self-attention units transforms the set of further state variable vectors on the input side of the at least one of the multi-head self-attention modules based on trainable model parameters to provide a further set of the further state variable vectors on the output side.

6. The method according to claim 1, wherein:
the anomaly prediction model is trained in a device-external central processing unit which is in communication connection with a plurality of device batteries in order to evaluate the temporal historical and/or predicted operating variable curves of the plurality of device batteries, and
the model parameters of the anomaly prediction model are transmitted to the corresponding technical devices after the training.

7. The method according to claim 1, wherein the determined fault comprises a sudden death, a knee point or a capacitance dip and/or a thermal event such as a thermal runaway.

8. The method according to claim 1, wherein:
an occurrence of a certain fault of the device battery is detected after a certain period of time depending on the time series of the input variable vectors, when the evaluation of the anomaly prediction model results in a probability for the corresponding fault class above a predetermined threshold value, and
the detection of the occurrence of the certain fault is signaled by issuing a warning to a user.

9. The method according to claim 1, wherein the historical temporal operating variable curve of several operating variables is determined by rolling sampling of operating variable curves of individual battery cells.

10. The method according to claim 1, wherein the data-based anomaly prediction model is regularly retrained based on new training data sets in the central processing unit.

11. The method according to claim 1, wherein an apparatus is configured to carry out the method.

12. The method according to claim 1, wherein a computer program comprises instructions that, when the computer program is executed by at least one data processing device, prompt the at least one data processing device to perform the method.

13. The method according to claim 1, wherein a non-transitory machine-readable storage medium comprising instructions that, when executed by at least one data processing device, prompt the at least one data processing device to perform the method.
